(19) United States
(12) Patent Application Publication
(10) Pub. No.: US 2025/0359097 A1
(43) Pub. Date: Nov. 20, 2025

(54) SCHOTTKY BARRIER DIODE

(71) Applicant: TDK CORPORATION, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 19/289,236

(22) Filed: Aug. 4, 2025

Related U.S. Application Data
(63) Continuation of application No. PCT/JP2024/005204, filed on Feb. 15, 2024.

(30) Foreign Application Priority Data
Feb. 24, 2023 (JP) 2023-027092

(51) Int. Cl. H10D 8/60; H10D 62/80

(52) U.S. Cl. CPC H10D 8/605; H10D 62/875

(57) ABSTRACT

Disclosed herein is a Schottky barrier diode that includes a semiconductor substrate and a drift layer made of gallium oxide, an anode electrode brought into Schottky contact with the drift layer, and a cathode electrode brought into ohmic contact with the semiconductor substrate. The drift layer has a trench at a position overlapping the anode electrode. The trench is covered at least at its bottom surface with a laminated insulating film and filled with a conductive material connected to the anode electrode. The laminated insulating has a structure in which first and second insulating films made of mutually different insulating materials are laminated. The insulating materials constituting the first and second insulating films have a bandgap equal to or higher than a bandgap of gallium oxide and have a dielectric constant equal to or higher than ½ of a dielectric constant of gallium oxide.

### CROSS-REFERENCE TO RELATED APPLICATION

This application claims the benefit of Japanese Patent Application No. 2023-027092, filed on Feb. 24, 2023, the entire disclosure of which is incorporated by reference herein.

### BACKGROUND OF THE ART

### Field of the Art

The present disclosure relates to a Schottky barrier diode and, more particularly, to a Schottky barrier diode using gallium oxide.

### Description of Related Art

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (Sic), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of 8 MV/cm, so that a Schottky barrier diode using gallium oxide is very promising as the switching element for a power device. An example of the Schottky barrier diode using gallium oxide is described in JP 2018-142577A.

A Schottky barrier diode described in JP 2018-142577A has a structure in which a plurality of trenches are formed in a gallium oxide layer, and an anode electrode is partially filled in the trenches through an insulating film. By thus forming a plurality of trenches in the gallium oxide layer, a mesa region positioned between the trenches becomes a depletion layer upon application of a backward voltage, so that a channel region of a drift layer is pinched off. Thus, a leak current upon application of the backward voltage can be significantly reduced.

### SUMMARY

A Schottky barrier diode according to an aspect of the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a trench at a position overlapping the anode electrode. The trench is covered at least at its bottom surface with a laminated insulating film and filled with a conductive material connected to the anode electrode. The laminated insulating film has a structure in which a plurality of insulating films including first and second insulating films made of mutually different insulating materials are laminated. The insulating materials constituting the first and second insulating films have a bandgap equal to or higher than a bandgap of gallium oxide and have a dielectric constant equal to or higher than ½ of a dielectric constant of gallium oxide.

### BRIEF DESCRIPTION OF THE DRAWINGS

The above features and advantages of the present disclosure will be more apparent from the following description of some embodiments taken in conjunction with the accompanying drawings, in which:

FIG. 1A is a schematic plan view illustrating the configuration of a Schottky barrier diode 1 according to a first embodiment of the present disclosure. FIG. 1B is a schematic cross-sectional view taken along the line A-A in FIG. 1A;

FIG. 2 is a schematic cross-sectional for explaining the structure of the laminated insulating film 70;

FIG. 3 is a table showing the relative dielectric constant, band gap, and dielectric breakdown field of each insulating material;

FIG. 4 is a schematic cross-sectional view illustrating the configuration of a Schottky barrier diode 2 according to a second embodiment of the technology described herein;

FIG. 5A to 5C are schematic cross-sectional views for explaining the positions of the inner walls of the central trench 61 and the outer peripheral trench 62 that are covered with the laminated insulating film 70;

FIG. 6 is a schematic cross-sectional view illustrating the configuration of a Schottky barrier diode 3 according to a third embodiment of the technology described herein;

FIG. 7 is a schematic cross-sectional view illustrating the configuration of a Schottky barrier diode 4 according to a fourth embodiment of the technology described herein;

FIG. 8 is a schematic cross-sectional view illustrating the configuration of a Schottky barrier diode 5 according to a fifth embodiment of the technology described herein;

FIG. 9 is a schematic cross-sectional view for explaining the structure of the laminated insulating film 70;

FIG. 10 is a schematic cross-sectional view illustrating the configuration of a Schottky barrier diode 6 according to a sixth embodiment of the technology described herein;

FIG. 11 is a schematic cross-sectional view illustrating the configuration of a Schottky barrier diode 7 according to a seventh embodiment of the technology described herein;

FIG. 12 is a schematic cross-sectional view illustrating the configuration of a Schottky barrier diode 8 according to a comparative example; and

FIGS. 13 to 15 are tables showing the results of the examples.

### DETAILED DESCRIPTION OF THE EMBODIMENTS

When a backward voltage is applied in the configuration where the trench is formed in the gallium oxide layer, a strong electric field is disadvantageously applied to an insulating film positioned at the trench bottom.

The present disclosure describes a technology for relaxing, in a Schottky barrier diode using gallium oxide, an electric field to be applied to the insulating film provided in the trench.

Hereinafter, some embodiments of the present disclosure will be described in detail with reference to the accompanying drawings.

### First Embodiment

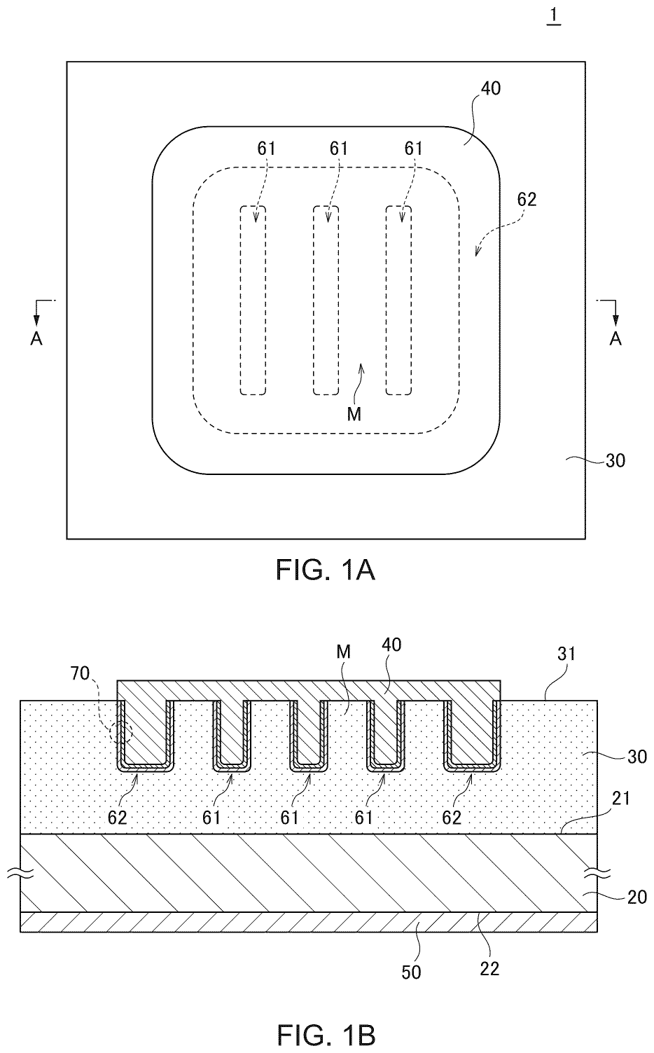

FIG. 1A is a schematic plan view illustrating the configuration of a Schottky barrier diode 1 according to a first embodiment of the present disclosure. FIG. 1B is a schematic cross-sectional view taken along the line A-A in FIG. 1A.

As illustrated in FIGS. 1A and 1B, the Schottky barrier diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n-layer, respectively.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20A, the planar size may be set to be about 2.4 mm×2.4 mm.

The semiconductor substrate 20 has an upper surface 21 positioned on the upper surface side in its mounted state and a back surface 22 positioned opposite the upper surface 12 and on the lower surface side in its mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600 V, the film thickness may be set to be about 10 μm.

There is formed, on an upper surface 31 of the drift layer 30, an anode electrode 40 which is brought into Schottky contact with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50 which is brought into ohmic contact with the semiconductor substrate 20. The cathode electrode 50 is formed of metal such as titanium (Ti). The cathode electrode 50 may have a multilayer structure of different metal films, such as Ti/Au or Ti/Al.

In the present embodiment, the drift layer 30 has a center trench 61 and an outer peripheral trench 62. The center and outer peripheral trenches 61 and 62 are formed so as to overlap the anode electrode 40 in a plan view and are filled with the same material as that of the anode electrode 40. However, the conductive material filled in the center and outer peripheral trenches 61 and 62 need not necessarily be the same as that of the anode electrode 40, but it is sufficient that the conductive material filled in the center and outer peripheral trenches 61 and 62 is electrically connected to the anode electrode 40. The center trench 61 is sandwiched by a mesa region M constituting a part of the drift layer 30. The outer peripheral trench 62 surrounds, in a ring shape, the mesa region M and center trench 61. The center and outer peripheral trenches 61 and 62 need not completely be separated but may be connected. The depths of the center and outer peripheral trenches 61 and 62 may be the same as or different from each other. The mesa region M is a part of the drift layer 30 that is defined by the center and outer peripheral trenches 61 and 62 and becomes a depletion layer when a backward voltage is applied between the anode electrode 40 and cathode electrode 50, so that a channel region of the drift layer 30 is pinched off, thereby significantly reducing a leak current upon application of a backward voltage.

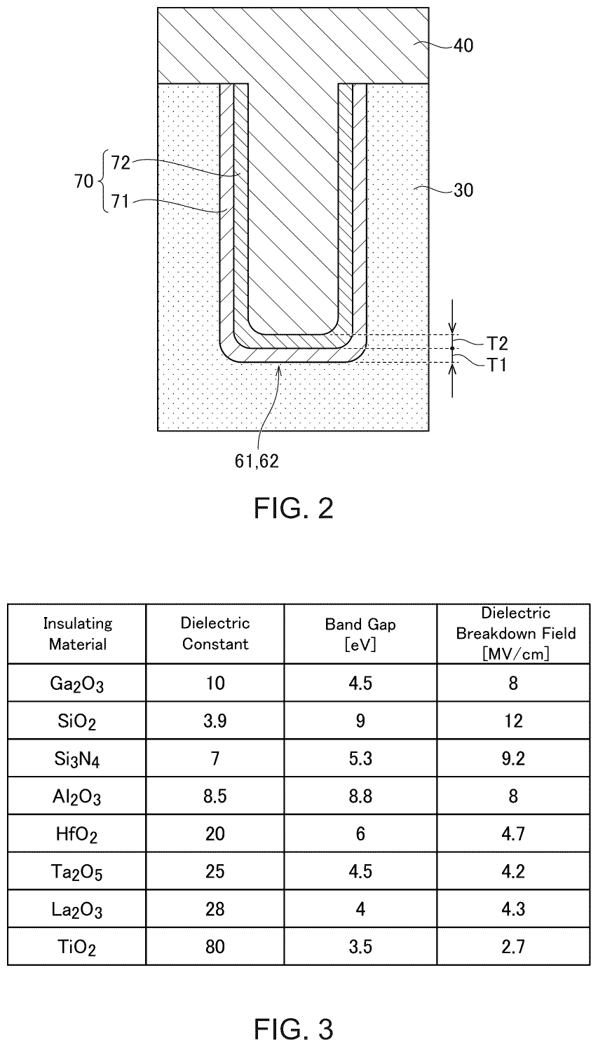

The center and outer peripheral trenches 61 and 62 are covered with a laminated insulating film 70. In the present embodiment, the entire inner wall (i.e., a bottom surface 32 and a side surface 33) of each of the center and outer peripheral trenches 61 and 62 are covered with the laminated insulating film 70. As illustrated in FIG. 2, in the present embodiment, the laminated insulating film 70 is composed of two laminated insulating films 71 and 72. The insulating film 71 is positioned outside, and the insulating 72 is positioned inside. Thus, the insulating film 71 contacts the drift layer 30 exposed to the inner wall of the center trench 61 or outer peripheral trench 62, while the insulating film 72 contacts the conductive material filled in the center trench 61 or outer peripheral trench 62. The film thicknesses of the insulating films 71 and 72 are defined by the film thickness on the bottom surface 32 of the center trench 61 and the film thickness on the bottom surface 32 of the outer peripheral trench 62, respectively. That is, a film thickness T1 of the insulating film 71 and a film thickness T2 of the insulating film 72 are each defined by the thickness illustrated in FIG. 2.

The insulating films 71 and 72 are made of mutually different insulating materials. As the insulating material of each of the insulating films 71 and 72, a material having a high bandgap and a high dielectric constant (relative permittivity) is selected. For example, it is necessary to select an insulating material having a bandgap equal to or higher than the insulating material of gallium oxide and a dielectric constant equal to or higher than ½ of the dielectric constant of gallium oxide. This is because when the bandgap of the insulating material constituting each of the insulating films 71 and 72 is lower than the bandgap of gallium oxide, a sufficient insulation property cannot be obtained upon application of a backward voltage, and when the dielectric constant of the insulating material constituting each of the insulating films 71 and 72 is less than ½ of the dielectric constant of gallium oxide, a high electric field is generated in the insulating films upon application of a backward voltage. The dielectric constant of the insulating material constituting each of the insulating films 71 and 72 may be equal to or higher than the dielectric constant of gallium oxide.

However, the bandgap and dielectric constant generally have a trade-off relation with each other, so that there are only limited insulating materials that satisfy the above conditions. Examples of the insulating material that satisfies the above conditions include Al₂O₃, HfO₂, Ta₂O₅, and Si₃O₄. As illustrated in FIG. 3, the bandgaps of Al₂O₃, HfO₂, Ta₂O₅, and Si₃O₄ are equal to or higher than the bandgap of gallium oxide, and the dielectric constants thereof are equal to or higher than ½ of the bandgap of gallium oxide. Among them, HfO₂ is equal to or higher in dielectric constant than the gallium oxide and may be selected for the insulating films 71 and 72. Further, Al₂O₃ has a very high bandgap and may also be selected for the insulating films 71 and 72. Although Si₃O₄ is not so high in dielectric constant, it has a high breakdown electric field and may be selected for the insulating films 71 and 72. The dielectric constant values shown in FIG. 3 are measured by a method using an impedance analyzer or a TM cavity resonator or by a frequency-change method, and the frequency at measurement time is 1 MHZ. The bandgap values shown in FIG. 3 are measured by a spectroscopic bandgap measurement method or a simple bandgap measurement based on XPS.

However, the insulating material constituting each of the insulating films 71 and 72 need not be pure Al₂O₃, pure HfO₂, pure Ta₂O₅, or pure Si₃O₄ but may contain impurities. That is, even when the insulating material constituting each of the insulating films 71 and 72 contains impurities, it is sufficient that the bandgap thereof is equal to or higher than the bandgap of gallium oxide and that the dielectric constant thereof is equal to or higher than ½ of the dielectric constant of gallium oxide.

On the other hand, SiO₂ is higher in bandgap and breakdown electric field but has a dielectric constant as low as 3.9 which is less than ½ of the dielectric constant of gallium oxide. Thus, using SiO₂ as the material of the insulating film 71 or 72 actually strengthens an electric field to be applied to the laminated insulating film 70, revealing that SiO₂ is not suitable for the insulating films 71 and 72. Further, La₂O₃ and TiO₂ are high in dielectric constant, but the bandgaps thereof are less than the bandgap of gallium oxide. Thus, using La₂O₃ or TiO₂ as the material of the insulating film 71 or 72 fails to obtain a sufficient insulation property upon application of a backward voltage, revealing that La₂O₃ and TiO₂ are not suitable for the insulating films 71 and 72.

Further, when a backward voltage is applied, an electric field is more likely applied to the insulating film 72 positioned on the inner side than the insulating film 71 positioned on the outer side, so that when there is a difference in dielectric constant between the insulating materials of the insulating films 71 and 72, an insulating film on the side at which the dielectric constant is low may be adopted as the insulating film 71, and an insulating film on the side at which the dielectric constant is high may be adopted as the insulating film 72. For example, when Al₂O₃ and HfO₂ are used as the materials of the insulating films 71 and 72, respectively, Al₂O₃ having a lower dielectric constant is used for the insulating film 71, and HfO₂ having a higher dielectric constant is used for the insulating film 72.

The film thicknesses of the insulating films 71 and 72 may be the same as or different from each other. Here, when a backward voltage is applied, a material having a low dielectric constant tends to be subject to a stronger electric field as the film thickness thereof increases, so that when there is a difference in film thickness between the insulating films 71 and 72, the film thickness of an insulating film made of a material having a low dielectric constant may be made small, and the film thickness of an insulating film made of a material having a high dielectric constant may be made large. For example, when Al₂O₃ and HfO₂ are used as the materials of the insulating films 71 and 72, respectively, an insulating film made of Al₂O₃ having a lower dielectric constant is made smaller in film thickness than an insulating film made of HfO₂ having a higher dielectric constant.

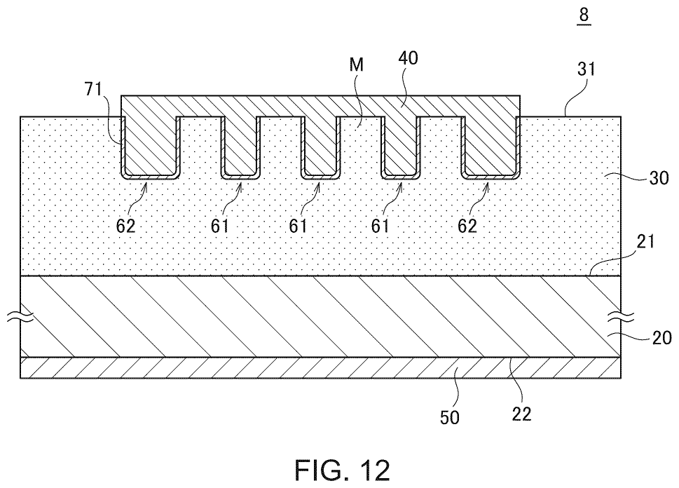

As described above, the Schottky barrier diode 1 according to the present embodiment has a configuration in which the inner wall of each of the center and outer peripheral trenches 61 and 62 is covered with the laminated insulating film 70 having a two-layer structure, so that an electric field to be applied to the laminated insulating film 70 upon application of a backward voltage is distributed to the insulating films 71 and 72, thus relaxing electric field strength to be applied to each of the insulating films 71 and 72. Thus, it is possible to reduce electric field strength to the insulating film 71 as compared with when the insulating film 71 of a single-layer structure is used (refer to a Schottky barrier diode 8 according to a Comparative Example 8 illustrated in FIG. 12).

### Second Embodiment

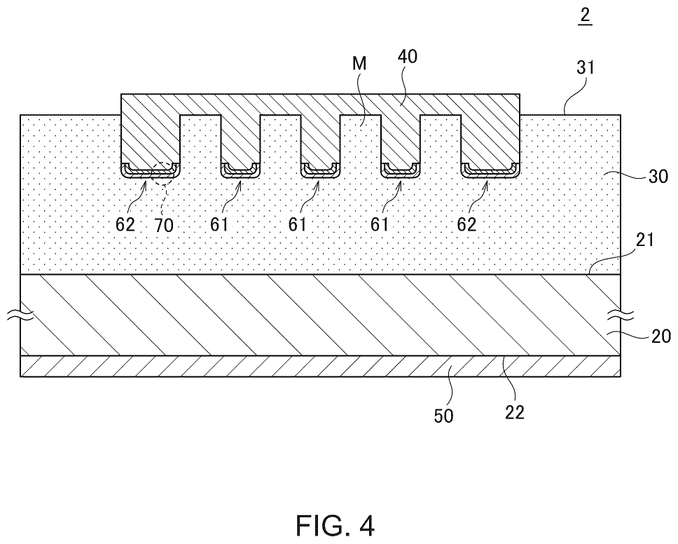

FIG. 4 is a schematic cross-sectional view illustrating the configuration of a Schottky barrier diode 2 according to a second embodiment of the technology described herein.

As illustrated in FIG. 4, the Schottky barrier diode 2 according to the second embodiment differs from the Schottky barrier diode 1 according to the first embodiment in that only the bottom surface 32 of the inner wall of each of the center and outer peripheral trenches 61 and 62 is covered with the laminated insulating film 70, whereas the side surface 33 of the inner wall of each of the center and outer peripheral trenches 61 and 62 is not covered with the laminated insulating film 70. Other basic configurations are the same as those of the Schottky barrier diode 1 according to the first embodiment, so the same reference numerals are given to the same elements, and overlapping description will be omitted.

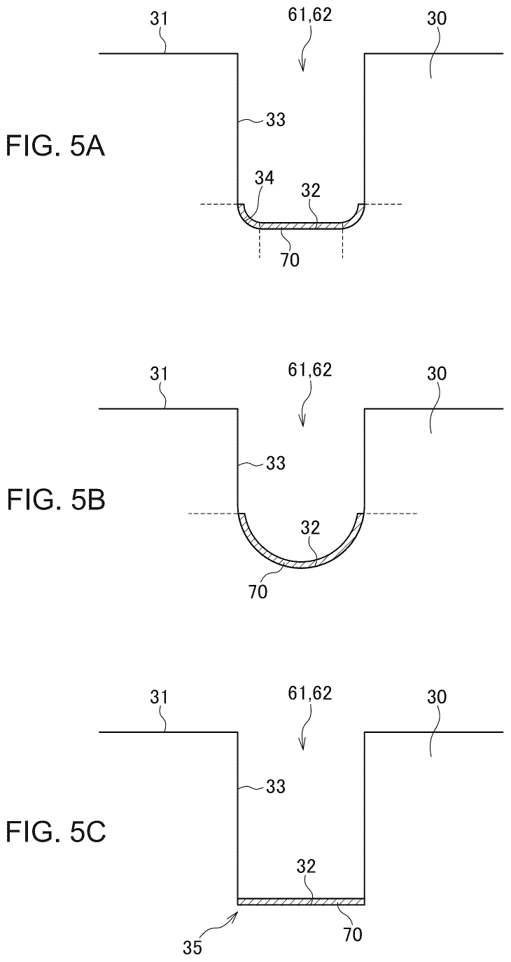

As illustrated in FIG. 5A, when the bottom surface 32 of each of the center and outer peripheral trenches 61 and 62 is horizontal, and a part positioned between the horizontal bottom surface 32 and vertical side surface 33 is a curved surface 34, the bottom surface 32 and curved surface 34 need to be covered with the insulating film 70. Further, as illustrated in FIG. 5B, when the bottom surface 32 of each of the center and outer peripheral trenches 61 and 62 is curved as a whole, the entire curved bottom surface 32 needs to be covered with the insulating film 70. Further, as illustrated in FIG. 5C, when the bottom surface 32 of each of the center and outer peripheral trenches 61 and 62 is horizontal, and a right-angle corner 35 exists between the horizontal bottom surface 32 and vertical side surface 33, the bottom surface 32 and corner 35 need to be covered with the insulating film 70. This is because that when a backward voltage is applied, the electric field strength becomes particularly high at the outer peripheral bottom portion of each of the center and outer peripheral trenches 61 and 62. That is, in the example illustrated in FIG. 5A, electric field strength is increased in the vicinity of the curved surface 34; in the example illustrated in FIG. 5B, electric field strength is increased in the vicinity of the curved bottom surface 32; and in the example illustrated in FIG. 5C, electric field strength is increased in the vicinity of the corner 35. Therefore, in the inner wall of each of the center and outer peripheral trenches 61 and 62, at least the above-mentioned portions need to be covered with the laminated insulating film 70.

Further, in the present embodiment, the side surface 33 of each of the center and outer peripheral trenches 61 and 62 is brought into Schottky contact with the anode electrode 40 without being covered with the laminated insulating film 70. As a result, the drift layer 30 and anode electrode 40 are brought into Schottky contact with each other not only at the upper surface 31 of the drift layer 30 but also at the side surface 33 of each of the center and outer peripheral trenches 61 and 62, so that an on-resistance is reduced as compared with when the entire wall of each of the center and outer peripheral trenches 61 and 62 is covered with the laminated insulating film 70. Further, the dopant concentration of the drift layer 30 can be suppressed, and thus deterioration in backward breakdown voltage can also be prevented.

### Third Embodiment

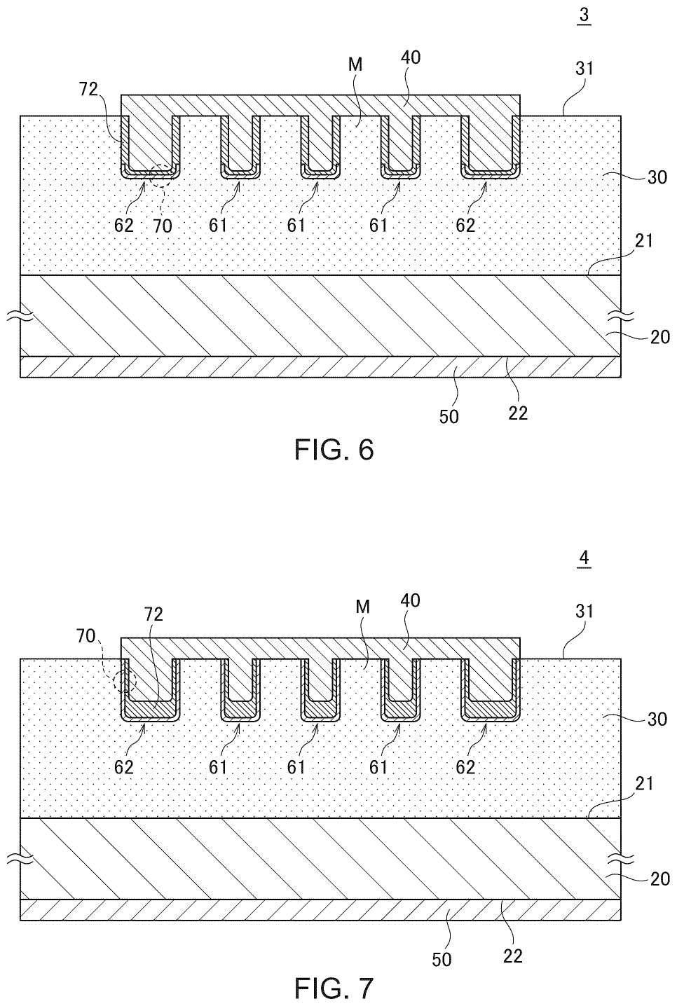

FIG. 6 is a schematic cross-sectional view illustrating the configuration of a Schottky barrier diode 3 according to a third embodiment of the technology described herein.

As illustrated in FIG. 6, the Schottky barrier diode 3 according to the third embodiment differs from the Schottky barrier diode 2 according to the second embodiment in that the side surface 33 of the inner wall of each of the center and outer peripheral trenches 61 and 62 is covered with the insulating film 72. Other basic configurations are the same those of the Schottky barrier diode 2 according to the second embodiment, so the same reference numerals are given to the same elements, and overlapping description will be omitted. Thus, the side surface 33 of each of the center and outer peripheral trenches 61 and 62 may be covered with the insulating film (71 or 72) of a single-layer structure.

### Fourth Embodiment

FIG. 7 is a schematic cross-sectional view illustrating the configuration of a Schottky barrier diode 4 according to a fourth embodiment of the technology described herein.

As illustrated in FIG. 7, the Schottky barrier diode 4 according to the fourth embodiment differs from the Schottky barrier diode 1 according to the first embodiment in that the insulating film 72 is selectively increased in thickness at a part thereof that covers the bottom surface 32. Other basic configurations are the same as those of the Schottky barrier diode 1 according to the first embodiment, so the same reference numerals are given to the same elements, and overlapping description will b omitted. Thus, the film thickness of the insulating film 71 or 72 need not necessarily be constant.

### Fifth Embodiment

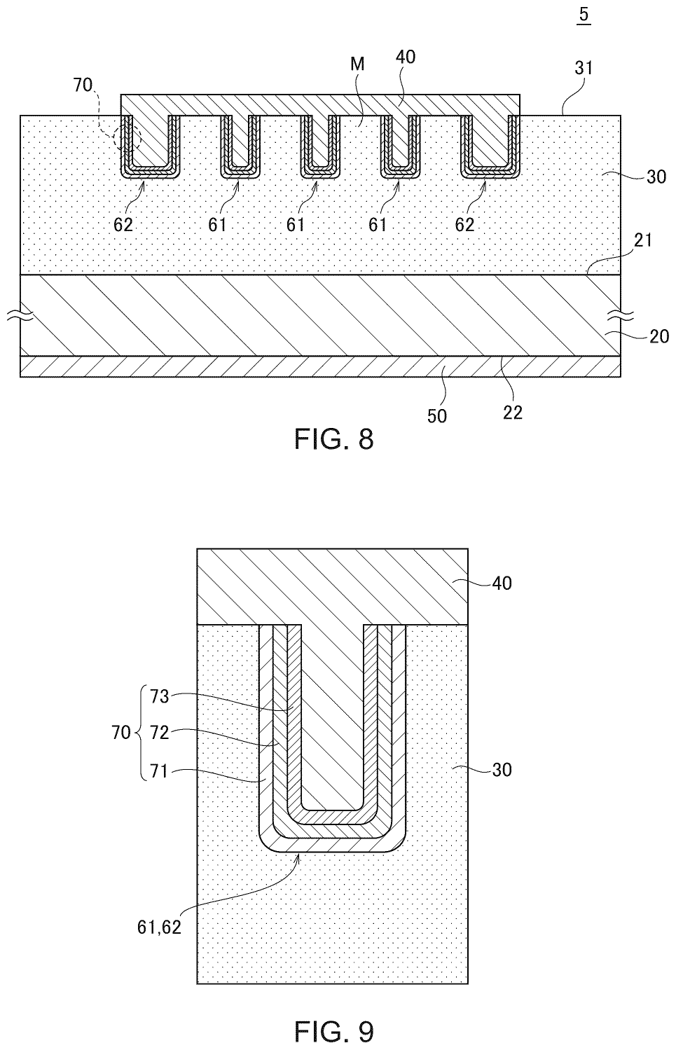

FIG. 8 is a schematic cross-sectional view illustrating the configuration of a Schottky barrier diode 5 according to a fifth embodiment of the technology described herein.

As illustrated in FIG. 8, the Schottky barrier diode 5 according to the fifth embodiment differs from the Schottky barrier diode 1 according to the first embodiment in that the laminated insulating film 70 has a three-layer structure. Other basic configurations are the same as those of the Schottky barrier diode 1 according to the first embodiment, so the same reference numerals are given to the same elements, and overlapping description will be omitted.

As illustrated in FIG. 9, in the present embodiment, the laminated insulating film 70 is composed of three laminated insulating films 71 to 73. The insulating film 71 is positioned outermost, the insulating film 73 is positioned innermost, and the insulating film 72 is positioned between the insulating films 71 and 73. Thus, the insulating film 71 contacts the drift layer 30 exposed to the inner wall of the center trench 61 or outer peripheral trench 62, while the insulating film 73 contacts the conductive material filled in the center trench 61 or outer peripheral trench 62.

The insulating films 71 and 72 are made of mutually different insulating materials, and the insulating films 72 and 73 are made of mutually different insulating materials. The insulating materials of the insulating films 71 to 73 may be all different from one another. For example, the insulating materials constituting the insulating films 71 to 73 may be those selected from a group consisting of Al₂O₃, HfO₂, and Si₃N₄. In this case, selecting HfO₂ having the highest dielectric constant as the material of the insulating film 72 can relax electric field strength to be applied to the outermost insulating film 71. Therefore, it is possible to use Al₂O₃ as the insulating material of the insulating film 71, HfO₂ as the insulating material of the insulating film 72, and Si₃N₄ as the insulating material of the insulating film 73.

### Sixth Embodiment

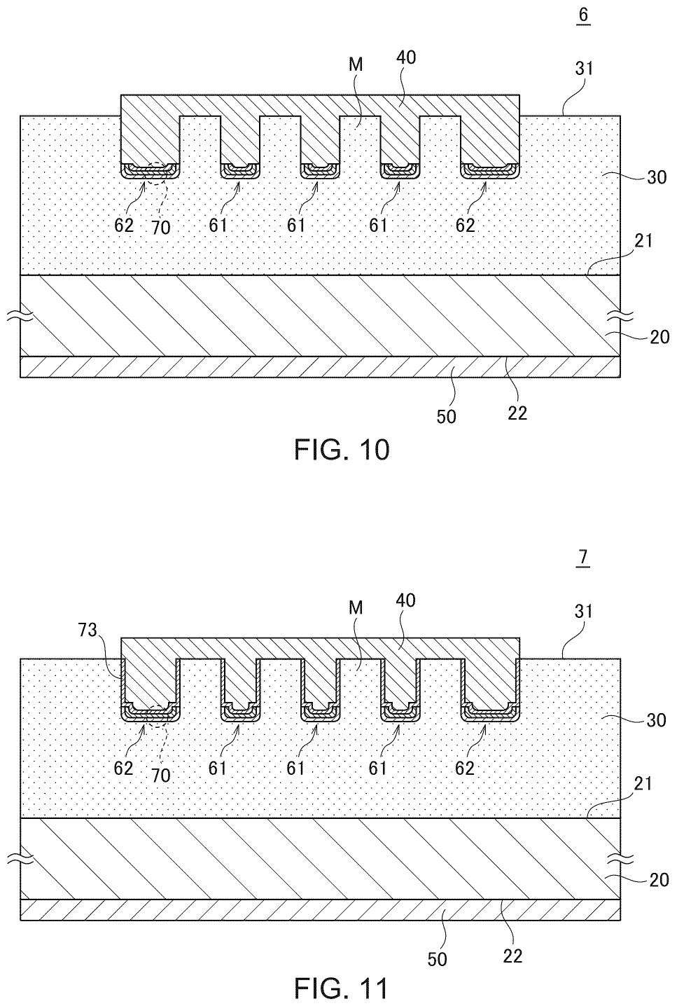

FIG. 10 is a schematic cross-sectional view illustrating the configuration of a Schottky barrier diode 6 according to a sixth embodiment of the technology described herein.

As illustrated in FIG. 10, the Schottky barrier diode 6 according to the sixth embodiment differs from the Schottky barrier diode 2 according to the second embodiment in that the laminated insulating film 70 has a three-layer structure. Other basic configurations are the same as those of the Schottky barrier diode 2 according to the second embodiment, so the same reference numerals are given to the same elements, and overlapping description will be omitted. Thus, even when the laminated insulating film 70 has a three-later structure, the laminated insulating film 70 may be removed from the side surface 33.

### Seventh Embodiment

FIG. 11 is a schematic cross-sectional view illustrating the configuration of a Schottky barrier diode 7 according to a seventh embodiment of the technology described herein.

As illustrated in FIG. 11, the Schottky barrier diode 7 according to the seventh embodiment differs from the Schottky barrier diode 6 according to the sixth embodiment in that the side surface 33 of the inner wall of each of the center and outer peripheral trenches 61 and 62 is covered with the insulating film 73. Other basic configurations are the same as those of the Schottky barrier diode 6 according to the sixth embodiment, so the same reference numerals are given to the same elements, and overlapping description will be omitted. Thus, the side surface 33 of the center and outer peripheral trenches 61 and 62 may be covered with the insulating film (71, 72, or 73) of a single-layer structure.

While some embodiments of the present disclosure has been described, the present disclosure is not limited to the above embodiment, and various modifications may be made within the scope of the present disclosure, and all such modifications are included in the present disclosure.

For example, although the center and outer peripheral trenches 61 and 62 are formed in the drift layer 30, one of the center and outer peripheral trenches 61 and 62 may be omitted.

The technology according to the present disclosure includes the following configuration examples but not limited thereto.

A Schottky barrier diode according to an aspect of the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a trench at a position overlapping the anode electrode. The trench is covered at least at its bottom surface with a laminated insulating film and filled with a conductive material connected to the anode electrode. The laminated insulating film has a structure in which a plurality of insulating films including first and second insulating films made of mutually different insulating materials are laminated. The insulating materials constituting the first and second insulating films have a bandgap equal to or higher than a bandgap of gallium oxide and have a dielectric constant equal to or higher than ½ of a dielectric constant of gallium oxide. Thus, an electric field to be applied to the laminated insulating film upon application of a backward voltage is distributed to the plurality of insulating films, thus relaxing electric field strength to be applied to each of the insulating films.

In the above Schottky barrier diode, the insulating material constituting at least one of the first and second insulating films may have a dielectric constant equal to or higher than the dielectric constant of gallium oxide. This can further relax electric field strength to be applied to each of the insulating films.

In the above Schottky barrier diode, the plurality of insulating films may further include a third insulating film. This can further relax electric field strength to be applied to each of the insulating films.

In the above Schottky barrier diode, each of the first and second insulating films may be made of any insulating material selected from a group consisting of Al₂O₃, HfO₂, Ta₂O₅, and Si₃O₄. This relaxes electric field strength to be applied to each of the insulating films as compared with when an insulating film of a single-layer structure made of any insulating material selected from the above group is used.

### EXAMPLES

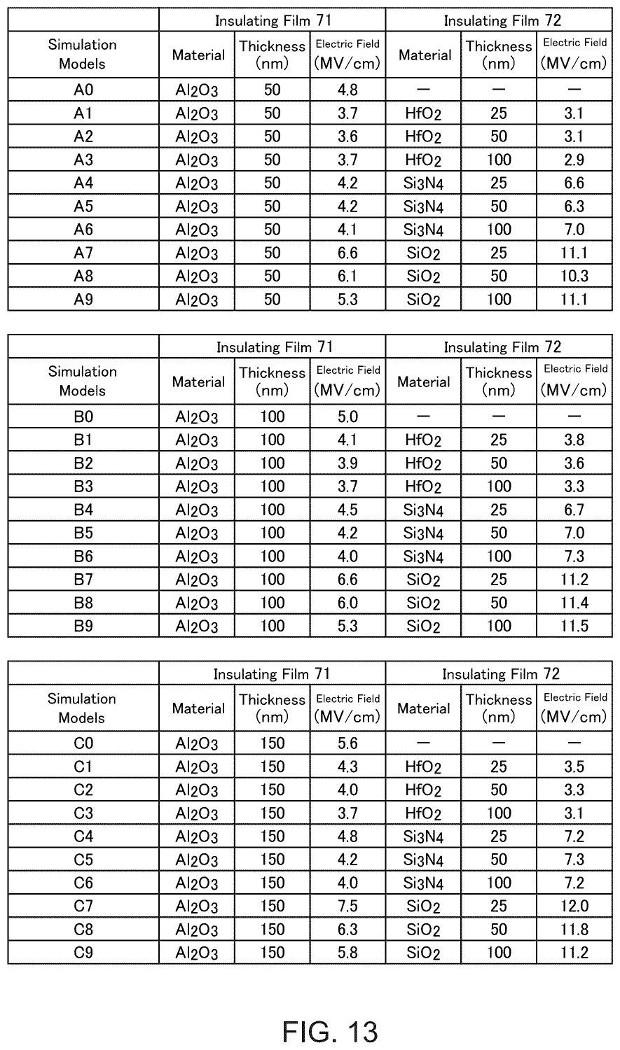

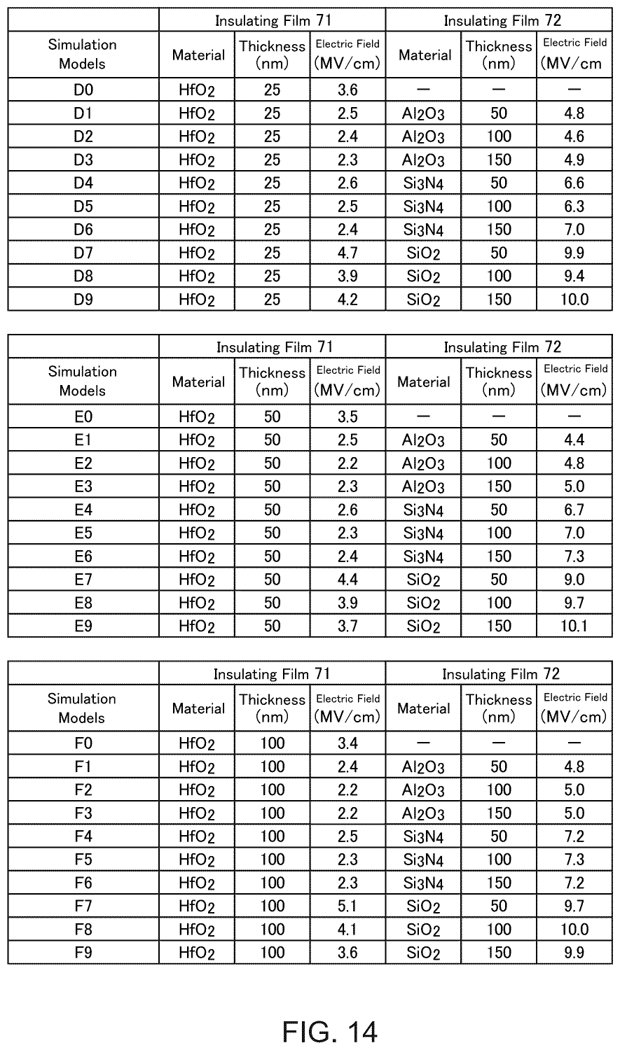

A plurality of simulation models having the same structures as those of the Schottky barrier diodes 1 and 8 illustrated in FIGS. 1 and 12 were assumed, and electric field strength to be applied to each of the insulating films 71 and 72 was simulated with a backward voltage of 1200 V applied between the anode electrode 40 and cathode electrode 50. The dopant concentration of the semiconductor substrate 20 was set to 1×10¹⁸ cm⁻³, and the dopant concentration of the drift layer 30 was to 3×10¹⁶ cm⁻³. The thickness of the drift layer 30 was set to 10 μm. The depths of the center and outer peripheral trenches 61 and 62 were both set to 2 μm. The width of the center and outer peripheral trenches 61 and 62 in the cross section illustrated in FIG. 1B and the width of the upper surface 31 of the drift layer 30 (i.e., width of the mesa region M) were both set to 1.0 μm. The anode electrode 40 was made of Ni, and the cathode electrode 50 was formed of a laminated film of Ti and Au. The materials and film thicknesses of the insulating films 71 and 72 in each simulation model are shown in FIGS. 13 and 14.

As shown in FIG. 13, as compared with the simulation models A0, B0, and C0 in which the insulating film 71 of a single-layer structure made of Al₂O₃ was used, electric field strength applied to the insulating film 71 was reduced in the simulation models A1 to A6, B1 to B6, and C1 to C6 in which the insulating film 72 made of HfO₂ or Si₃O₄ was additionally provided. Electric field strength to be applied to each of the insulating films 71 and 72 tended to become lower as the film thickness of the insulating film 71 was reduced and as the film thickness of the insulating film 72 was increased. In particular, in the simulation models A1 to A3, B1 to B3, and C1 to C3 in which HfO₂ was used as the material of the insulating film 72, electric field strength applied to the insulating film 71 was significantly reduced. On the other hand, as compared with the simulation models A0, B0, and C0 in which the insulating film 71 of a single-layer structure was used, electric field strength applied to the insulating film 71 was actually increased in the simulation models A7 to A9, B7 to B9, and C7 to C9 in which the insulating film 72 made of SiO₂ was additionally provided.

As shown in FIG. 14, as compared with the simulation models D0, E0, and F0 in which the insulating film 71 of a single-layer structure made of HfO₂ was used, electric field strength applied to the insulating film 71 was reduced in the simulation models D1 to D6, E1 to E6, and F1 to F6 in which the insulating film 72 made of Al₂O₃ or Si₃O₄ was additionally provided. No strong correlation was observed between the film thicknesses of the insulating films 71 and 72 and electric field strength applied to the insulating films 71 and 72. On the other hand, as compared with the simulation models D0, E0, and F0 in which the insulating film 71 of a single-layer structure was used, electric field strength applied to the insulating film 71 was actually increased in the simulation models D7 to D9, E7 to E9, and F7 to F9 in which the insulating film 72 made of SiO₂ was additionally provided.

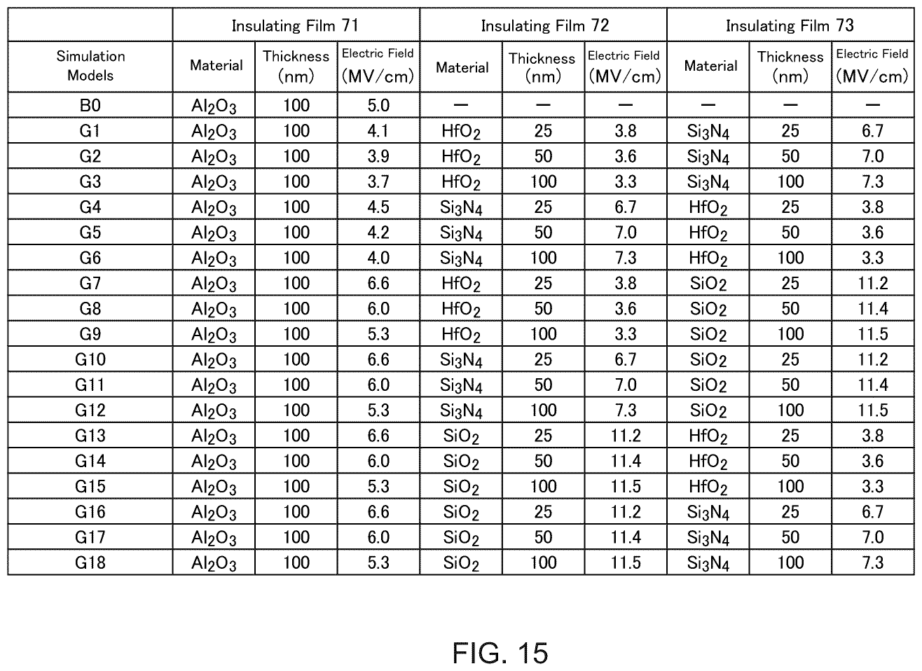

Further, a plurality of simulation models having the same structure as that of the Schottky barrier diode 5 illustrated in FIG. 8 were assumed, and electric field strength to be applied to each of the insulating films 71 to 73 was simulated with a backward voltage of 1200 V applied between the anode electrode 40 and cathode electrode 50. The insulating film 71 was made of Al₂O₃, and the film thickness thereof was fixed to 100 nm. The materials and film thicknesses of the insulating films 72 and 73 in each simulation model are shown in FIG. 15.

As shown in FIG. 15, as compared with the simulation model B0 in which the insulating film 71 of a single-layer structure made of Al₂O₃ was used, electric field strength applied to the insulating film 71 was reduced in the simulation models G1 to G6 in which the insulating films 72 and 73 made of HfO₂ or Si₃O₄ were additionally provided. On the other hand, as compared with the simulation model B0 in which the insulating film 71 of a single-layer structure was used, electric field strength applied to the insulating film 71 was actually increased in the simulation models G7 to G18 in which SiO₂ was used as the material of one of the insulating films 72 and 73.

What is claimed is:

1. A Schottky barrier diode comprising:
a semiconductor substrate made of gallium oxide;
a drift layer made of gallium oxide and provided on the semiconductor substrate;
an anode electrode brought into Schottky contact with the drift layer; and
a cathode electrode brought into ohmic contact with the semiconductor substrate,
wherein the drift layer has a trench at a position overlapping the anode electrode,
wherein the trench is covered at least at its bottom surface with a laminated insulating film and filled with a conductive material connected to the anode electrode,
wherein the laminated insulating film has a structure in which a plurality of insulating films including first and second insulating films made of mutually different insulating materials are laminated, and
wherein the insulating materials constituting the first and second insulating films have a bandgap equal to or higher than a bandgap of gallium oxide and have a dielectric constant equal to or higher than ½ of a dielectric constant of gallium oxide.

2. The Schottky barrier diode as claimed in claim 1, wherein the insulating material constituting at least one of the first and second insulating films has a dielectric constant equal to or higher than the dielectric constant of gallium oxide.

3. The Schottky barrier diode as claimed in claim 1, wherein the plurality of insulating films further include a third insulating film.

4. The Schottky barrier diode as claimed in claim 1, wherein each of the first and second insulating films is made of any insulating material selected from a group consisting of Al₂O₃, HfO₂, Ta₂O₅, and Si₃O₄.

5. The Schottky barrier diode as claimed in claim 1,
wherein a dielectric constant of the insulating material constituting the second insulating film is higher than a dielectric constant of the insulating material constituting the first insulating film, and
wherein the first insulating film is positioned between the bottom surface of the trench and the second insulating film.

6. The Schottky barrier diode as claimed in claim 1,
wherein a dielectric constant of the insulating material constituting the second insulating film is higher than a dielectric constant of the insulating material constituting the first insulating film, and
wherein the second insulating film is thicker than the first insulating film.
